(19) United States
(12) Patent Application Publication
(10) Pub. No.: US 2003/0185062 A1
(43) Pub. Date: Oct. 2, 2003

(54) Proximity lookup for large arrays

(75) Inventors: Phillip G. Wald, Boise, ID (US); Casey Kurth, Eagle, ID (US); Scott Derner, Meridian, ID (US)

Correspondence Address: FOGG SLIFER POLGLAZE LEFFERT & JAY, P.A., Attn: Daniel J. Polglaze, P. O. Box 581009, Minneapolis, MN, 55402, US

(73) Assignee: Micron Technology, Inc.

(21) Appl. No.: 10/109,068

(22) Filed: Mar. 28, 2002

(51) Int. Cl. G11C 7/00

(52) U.S. Cl. 365/200

(57) ABSTRACT

Proximity effects of close neighbors to a cell that is to be printed are compensated for before printing. A lookup table containing a set of all known proximity mappings of neighbors to the cell to be printed is used to match a placement configuration, and a known correction is applied before printing the cell.

The present invention relates generally to semiconductor memories, and more specifically to a read only memory (ROM) embedded in a dynamic random access memory (DRAM).

### BACKGROUND OF THE INVENTION

As memory cells continue to get smaller and densities on memories continue to increase, the proximity of placements, that is features to be printed onto a board, chip, or the like, has become increasingly important. When a feature is printed on a chip or board or the like, there are lithography effects that change the actual final size and shape of the feature. Different patterns of neighboring cells or placements result in different proximity effects.

Proximity correcting software has recently become a necessity in printing cells on silicon. Implementation of proximity correcting software has been widely used on periphery non-repeating structures and was run up to and including the edge of large arrays. An array, especially a random access memory array, is typically drawn repetitively, and proximity corrections are not run on each cell due to the repetitive nature of the array.

In standard arrays, when one cell is adjusted, the remaining cells of the array are adjustable in the same fashion. In non-standard arrays, however, proximity effects require more attention. Several approaches to proximity correction size a structure after the cells have been printed on the array. However, once the cells are placed on the array, proximity effects have been introduced, so if a cell is printed in close proximity to another cell, and the cells affect each other, the actual printed size of the cells may create an overlap of cells, leading to a short in the array, and unusable cells.

The lithography effects of printing in close proximity to another cell cause an effect in the final outcome in the feature dimensions. It is critical especially in transistors to control L dimensions with decreasing sizes in order to meet all conditions of the actual device being printed.

Therefore, there is a need in the art for an improved method for handling proximity effects in cell printing.

### SUMMARY

In one embodiment, a method for determining a printing pattern in a ROM embedded DRAM includes determining a set of closest neighbors to a desired printing location, looking up proximity effects for the determined closest neighbors, and printing a cell using a known printing footprint based on proximity effects.

In another embodiment, a method for printing cells in a ROM embedded DRAM includes determining a maximum distance at which proximity effects will be considered, determining a configuration of cells around a cell to be printed, comparing the determined configuration against a table of known configurations, and printing the cell with a correction associated with the known configuration that matches the determined configuration.

In yet another embodiment, a method of printing contacts in a ROM embedded DRAM includes analyzing a pattern of predefined neighbors to a contact to be printed, selecting a printing pattern for the contact from a lookup table containing possible nearest neighbor combinations, and printing the contact with the selected printing pattern.

In still another embodiment, a ROM embedded DRAM includes a random access memory having a first portion programmable as a read only memory and a second portion programmable as a random access memory, wherein the second portion has a proximity corrected printing layout.

Other embodiments are described and claimed.

### BRIEF DESCRIPTION OF THE DRAWINGS

FIG. 1 is a block diagram of a ROM embedded DRAM on which embodiments of the present invention are practiced;

FIG. 2 is a flow chart diagram of a method according to one embodiment of the present invention;

FIG. 3 is a diagram of a typical proximity testing grid according to another embodiment of the present invention;

FIG. 3A is a diagram of another proximity testing grid according to another embodiment of the present invention;

FIG. 3B is a diagram showing a typical mirrored proximity correction according to another embodiment of the present invention;

FIG. 3C is a table showing possible graphical proximity corrections according to another embodiment of the present invention;

FIG. 4 is a flow chart diagram of another embodiment of the present invention; and

FIG. 5 is a block diagram of a ROM embedded DRAM according to another embodiment of the present invention.

### DETAILED DESCRIPTION

In the following detailed description of the embodiments, reference is made to the accompanying drawings which form a part hereof, and in which is shown by way of illustration specific embodiments in which the invention may be practiced. It is to be understood that other embodiments may be utilized and structural or logical changes may be made without departing from the scope of the present invention.

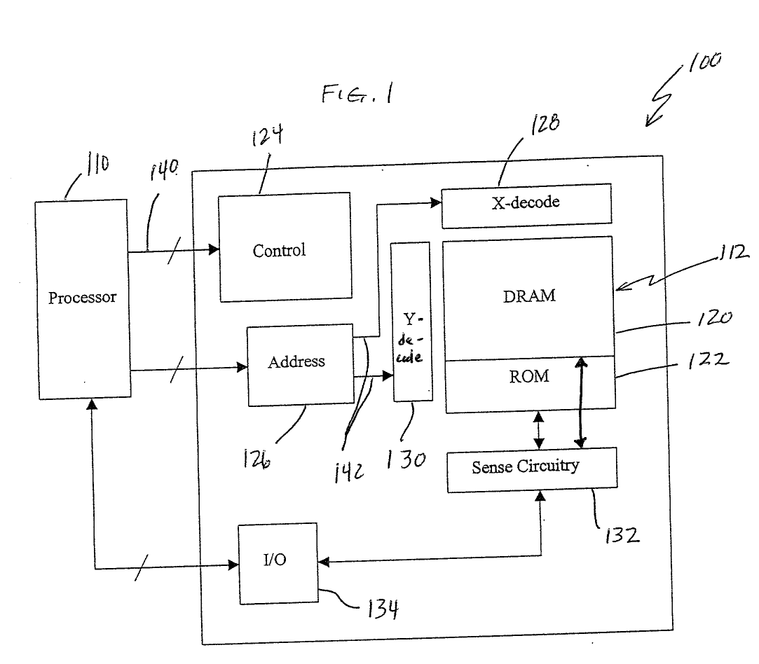

Referring to FIG. 1, a simplified block diagram of a ROM embedded DRAM 100 of the present invention is described. The memory device can be coupled to a processor 110 for bi-directional data communication. The memory includes an array of memory cells 112. The array includes a dynamic (DRAM) portion 120 and a read only (ROM) portion 122. The ROM array is “embedded” in the dynamic memory and may include some dynamic cells. Control circuitry 124 is provided to manage data storage and retrieval from the array in response to control signals 140 from the processor. Address circuitry 126, X-decoder 128 and Y-decoder 130 analyze address signals 142 and storage access locations of the array. Sense circuitry 132 is used to read data from each of the DRAM and ROM sections of the array and couple output data to I/O circuitry 134. The I/O circuitry operates in a bi-directional manner to receive data from processor 110 and pass this data to array 112.

Dynamic memories are well known, and those skilled in the art will appreciate that the above-described ROM embedded DRAM has been simplified to provide a basic understanding of DRAM technology and is not intended to describe all of the features of a DRAM. The present invention uses the basic architecture and fabrication techniques of a DRAM and provides an embedded ROM array for non-volatile storage of data. This data can be used to store boot-type data for a system, a non-volatile look-up table, or other data that does not require a dedicated ROM memory device. Embedding ROM storage in a DRAM is most economically beneficial if the DRAM is not substantially altered during fabrication or operation. That is, small fabrication changes allow the embedded memory to be fabricated using known techniques. Further, it is desired to maintain operation of the memory in a manner that is externally transparent. As such, an external processor, or system, does not need special protocol to interface with the embedded memory.

One technique for physically programming ROM embedded cells is described in U.S. Pat. No. 6,134,137 issued Oct. 17, 2000 entitled “ROM-Embedded-DRAM”, incorporated herein by reference. U.S. Pat. No. 6,134,137 teaches that slight modifications in fabrication masks allow DRAM cells to be hard programmed to V_{cc} or Vₛₛ by shorting the cell to word lines. The memory reads the ROM cells in a manner that is identical to reading the DRAM cells. As described below, the present invention provides an improved ROM embedded DRAM.

To implement a ROM embedded DRAM, a ROM mask is necessary to implement an implant for threshold voltage (V_{T}) adjustment or an etch or the like to short another node. These masks are typically not repeatable in the array but are required to match the requested programming of the ROM embedded DRAM. The implementation of the embodiments of the present invention assumes an underlying standard array of repetitive cells is made and that an instance has been placed on those cells which require programming.

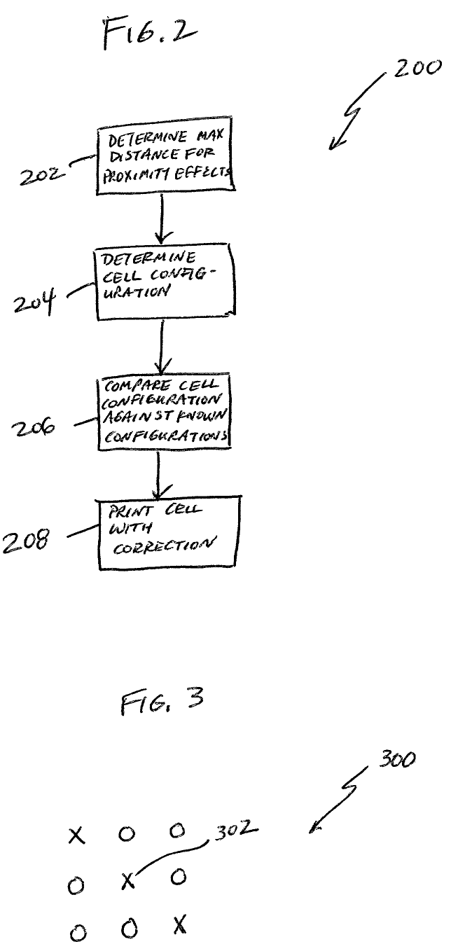

FIG. 2 is a flow chart diagram of a method 200 according to one embodiment of the present invention. Method 200 comprises determining a maximum distance at which proximity effects will be considered in block 202, determining a configuration of cells around a cell to be printed in block 204, comparing the determined configuration against a table of known configurations in block 206, and printing the cell with a correction associated with the known configuration that matches the determined configuration in block 208.

The table of known configurations is generated in one embodiment by looking at all known configurations for neighbors of a cell to and the resultant printing pattern that is to be expected without proximity correction. In one embodiment, the neighbors are the nearest neighbors, that is the neighboring cell or contact positions directly adjacent the cell or contact to be printed. In another embodiment, the neighbors are the nearest neighbors and the second nearest neighbors. In still another embodiment, it is determined at what distance from the cell or contact to be printed that neighbors have a proximity effect, and the neighbors are all those neighbors that contribute non-negligibly to any proximity effect.

In one embodiment, software analyzes the neighbor configuration for a cell. The neighbor configuration is whatever neighbor configuration is predetermined to affect the cell, that is all neighbors having proximity effects. The neighbor effects for the possible neighbor configurations are stored in a separate lookup table or register. Once the neighbor configuration for neighbors known to have proximity effects is completed, the resulting neighbor configuration is compared against the lookup table or register of known configurations, and a match is made. Once the match is made, a proximity correction for the determined configuration is known, and the cell or contact is printed with the proximity correction.

The lookup table in one embodiment determines what the actual printed cell will look like given the programming state of its nearest neighbors up to a certain distance, in one embodiment 10 micrometers. All neighbors within the certain distance are analyzed with respect to their configuration around the cell to be printed. Since DRAM cells typically contain two bits laid out symmetrically around a digit contact, orientation of the placed cell or correction is important as well in certain embodiments. In these embodiments, information about orientation of the cell is provided prior to making a proximity lookup analysis.

Proximity effects are small over distance, and therefore only cells that are close to the cell being printed affect the sizing issue of the cell. A determination is made as to how far a cell must be from another before the proximity effects between the cells are negligible.

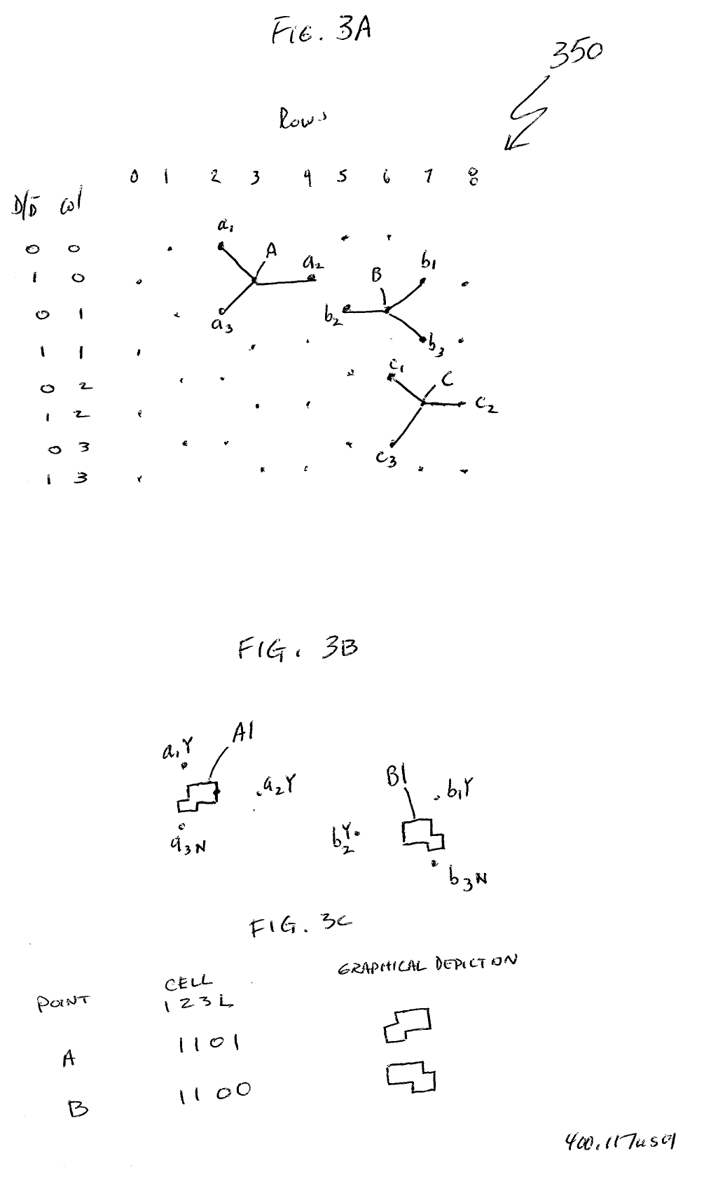

In one embodiment, the lookup table is generated either by running proximity algorithms on small arrays or by experimentation to determine the best correction to maintain shape and size and also to determine how many cells are required to be nearest neighbors, and to what distance a cell must be isolated from other cells to be considered to be isolated for purposes of proximity corrections. In operation, assume that a cell centered in a 3×3 grid gives sufficient information to determine proximity sizing of the cell. Such a grid 300 is shown in FIG. 3. The cell for which proximity correction is desired is in this example cell 302. This cell is at relative row and column address (1,1) in grid 300, and is denoted by an X as having an instance or needing to be programmed.

In the example above, the mapping may be done by using a 1 or TRUE for placement of an instance or 0 or FALSE for the lack thereof. Starting at relative row 0 and wrapping around from relative column 2 to 0 at the end of the array gives a mapping in Table 1 of correction as follows:

TABLE 1

| | Column | | |
|---|---|---|---|
| Row | 1 | 0 | 0 |
| | 0 | 1 | 0 |
| | 0 | 0 | 1 |

For each occurrence of the proximity mapping 100010001, a known correction is implemented on the instance. The known proximity correction indicates the correction to be made on the instance during printing. The correction may entail changing the geometric shape of the printed cell, or resizing the cell to make it larger or smaller, or a combination thereof. If no instance is placed on a particular location, no analysis is done, and the next location is checked. Each cell of the array is analyzed using the proximity mapping, and each proximity mapping is compared against a table containing the known corrections for the specific proximity mapping.

For the 3×3 grid 300, the fifth digit of the proximity mapping is the instance where there is or is not to be a placement. Therefore, if proximity mapping indicates the fifth digit to be a zero, no further analysis is necessary. Alternatively, such a check as to whether a placement is to be made is made in another embodiment before any proximity checking is performed. If proximity mapping indicates the fifth digit to be a one, proximity correction analysis continues, and a correction is made. Multiple proximity mappings may point to the same correction.

The proximity analysis is completed for each cell in an array. If a cell does not have a placement to be printed, it is skipped and the next position in the overall array is checked. The process continues until all the cells have been analyzed. The embodiments do not run a sizing algorithm on all cells. Instead, a sizing lookup is run only on those cells that are required to be sized due to their proximity to their nearest neighbors, as determined by the layout of the array and the effects on a placement of other close cells. Therefore, in another embodiment, large areas without features are skipped entirely in the analysis to save time and effort.

Given known patterns of neighbor cells to a printed cell, the proximity effects are stored in a lookup table, so that when the same proximity mapping is identified for a different cell, the print template with proximity corrections is retrieved and the cell is printed with proximity correction. Factors that influence the proximity effects include by way of example only and not by way of limitation topographical characteristics, the distance over which proximity effects are tangible, and the like.

Another grid 350 representing an array pattern is shown in FIG. 3A. Grid 350 is a representation of a non-orthogonal array. This is a typical configuration for storage cells in a DRAM employing an 8F² architecture. The issues with respect to proximity correction in a non-orthogonal array are slightly different from those in an orthogonal array, since symmetries play a more important role in the array. FIG. 3A shows one type of interaction between symmetry and proximity corrections. For cells A, B, and C, the nearest neighbors a1, a2, and a3, b1, b2, and b3, and c1, c2, and c3, are shown. The nearest neighbors are in this configuration the three closest cells connected to cells A, B, and C by lines drawn therebetween. Graphically, it is clear that if points A and B are to be printed, and if the a1, a2, a3 and b1, b2, b3 printings are to be equivalent, that the proximity correction to point B is identical to that of point A, with the one exception being that it is a mirror image of that for point A. The proximity correction to point C is identical to that of point A with the translation assuming the a1, a2, a3 and c1, c2, c3 printings are to be equivalent.

Implementation of proximity correction in programmable arrays is in one embodiment used for the smallest identifiable repeating structure for corrections with mirroring, translation, rotation, and the like to advantage in the implementation of proximity correction in programmable arrays.

One potential correction example is shown in FIG. 3B. The marks Y and N indicate whether there is to be a correction at the specific location, with Y indicating that a cell is to be placed and N indicating that no cell is to be placed at a location that is one of the surrounding locations to the specific location. Since the printing of points a1, a2, a3 and b1, b2, b3 are equivalent, and the pattern of neighbors for points A and B are mirrored, the actual printed corrections A1 and B1 are mirror images of one another.

Table 2 gives information for the eight cells associated with points A and B as shown in FIG. 3A. Rows and columns are listed using binary equivalents. Digit and digit bar D/D* is the least significant column address. D/D* is an important consideration with respect to whether placement of a cell represents a 0 or a 1 in a ROM embedded DRAM.

TABLE 2

| | | | | | Cell |
|---|---|---|---|---|---|
| Point | Row | Column | D/D* | Placement | 123L |
| a1 | 0010 | 00 | 0 | 1 | |
| a2 | 0100 | 00 | 1 | 1 | |
| a3 | 0010 | 01 | 0 | 0 | |
| A | 0011 | 00 | 1 | 1 | 1101 |
| b1 | 0111 | 00 | 1 | 1 | |
| b2 | 0101 | 01 | 0 | 1 | |
| b3 | 0111 | 01 | 1 | 0 | |
| B | 0110 | 01 | 0 | 1 | 1100 |

A programming algorithm sets up a table for a given array such as Table 2. The appropriate placement or non-placement of a programming marker in the placement column is already present from the programming algorithm operation. The proximity algorithm then runs through the placement column to calculate whether the nearest neighbors to the specific cell have a placement for each cell that has a programming marker. In various embodiments, nearest neighbors are determined by simple binary addition and subtraction of column/D/D* and/or the row address. One addition and subtraction algorithm flips on rows based on the least significant row address. Each marker's nearest neighbor is given a 1 or a 0 value depending on whether there is a placement or not. These three neighbors are each assigned a bit, and are shown appended to Table 2 in the Cell 123L column. These appended bits provide information on the correction or placement of a cell. For the three nearest neighbors, these is a maximum of eight correction possibilities. The least significant row address is again used to determine if a cell is mirrored or not.

FIG. 3C shows a partial table of one embodiment of a graphical correction scheme according to another embodiment of the present invention. For the Cell 123L column variations for points A and B of Table 2, a graphical depiction of the printing pattern is shown. The graphical depiction for point B mirrors that for point A, as is determined by the Least significant row address indicated in the Cell 123L column.

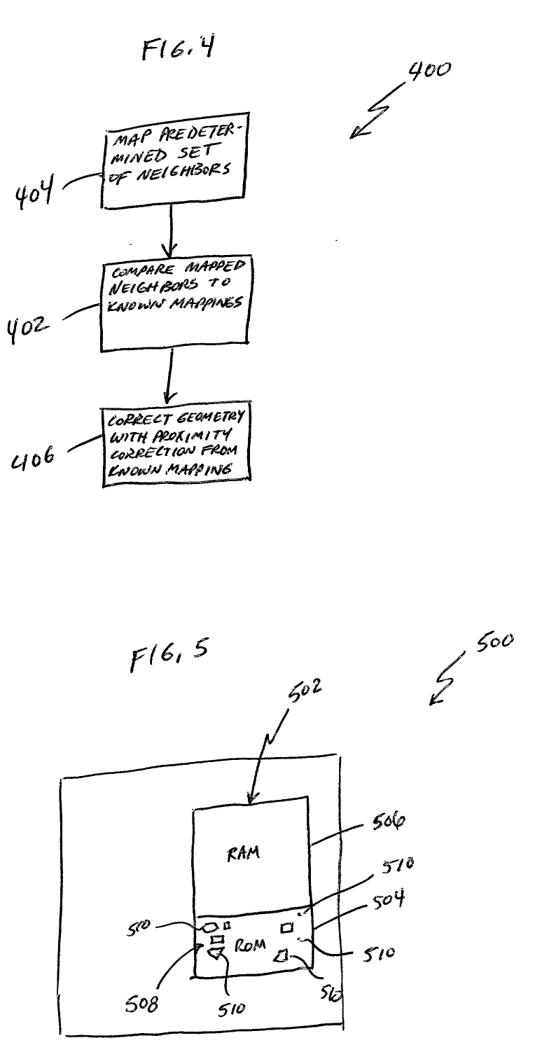

A method 400 for generating proximity corrections in a memory cell printing according to another embodiment of the invention is shown in FIG. 4. Method 400 comprises mapping a predetermined set of neighbors to the cell to be printed in block 402, comparing the mapped set of neighbors to a set of known mappings having known proximity corrections in block 404, and correcting a geometry of the memory cell to be printed according to a known proximity correction that matches the mapped set of neighbors in block 406. The known proximity correction is in one embodiment stored in a lookup table containing all possible known mappings, each having its own associated proximity correction factor.

A ROM embedded DRAM 500 according to another embodiment of the present invention is shown in FIG. 5. ROM embedded DRAM 500 comprises a random access memory 502 having a first portion 504 programmable as a read only memory and a second portion 506 programmable as a random access memory. The second portion has a proximity corrected printing layout 508 based on proximity corrections made to the reticle or database used for printing the reticle. The proximity corrections include resized and reshaped placements, the resizing a reshaping performed before the printing process by using one of the methods described above. The proximity corrected printing layout 508 comprises a plurality of printed cells 510, each cell being a proximity corrected printed cell.

It should be understood that actual physical layout and the layout the customer expects are sometimes different based on topological effects. For example, in laying out a ROM embedded DRAM array, the physical location of a cell and its address may be different. The topological characteristics of the ROM embedded DRAM may require such differences. It is sufficient that the correction for the ROM embedded DRAM is programmed when the ROM embedded DRAM is printed, so that the process is seamless to the customer.

While the methods and apparatuses above have been described with respect to memory cells, they are equally applicable to other structures such as gate arrays or other random arrays, non-standard arrays, or repetitive arrays of potential placement sites that do not have a plcement at every site.

### CONCLUSION

An analysis of the nearest neighbors to a placement to be printed in a memory is made to determine a proximity mapping of the nearest neighbors. The nearest neighbors are those neighbors that have a tangible effect on the lithography and etch characteristics of the cell to be printed. Using a lookup table after an analysis of the nearest neighbors to a placement of a cell to be printed in a memory device, a proximity correction for the specific pattern of placements around the cell to be printed is retrieved. The lookup table contains proximity mappings for each of the nearest neighbor configurations possible in the memory, and has a desired printing size and shape for each mapping to allow the final feature printed on the memory chip or board to be appropriate for proximity effect correction upon printing.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A method for making proximity corrections in memory cell printing, comprising:
analyzing a predetermined set of neighbors to a cell to be printed; and
determining a printing pattern for the cell based on the analysis of the predetermined set of neighbors.

2. The method of claim 1, wherein analyzing a predetermined set of neighbors comprises mapping each of the predetermined set of neighbors to determine which of the neighbors is to be printed.

3. The method of claim 1, wherein the analyzed predetermined set of neighbors is converted to a binary word, and wherein determining a printing pattern comprises matching the binary word to a lookup table containing all known binary words for the predetermined set of neighbors.

4. The method of claim 3, and further comprising:
applying a correction for the matched binary word based on a matched binary word correction.

5. A method for determining a printing pattern in a ROM embedded DRAM, comprising:
determining a set of closest neighbors to a desired printing location;
looking up proximity effects for the determined closest neighbors;
printing a cell using a known printing footprint based on proximity effects.

6. The method of claim 5, wherein looking up proximity effects comprises:
matching the determined set of closest neighbors to a set of known closest neighbors; and
applying a proximity correction associated with the matched set of closest neighbors to the cell to be printed.

7. The method of claim 5, wherein determining a set of closest neighbors comprises:
mapping instances of neighbors within a certain predefined distance from the cell to be printed.

8. A method for generating proximity corrections in a memory cell printing, comprising:
mapping a predetermined set of neighbors to the cell to be printed;
comparing the mapped set of neighbors to a set of known mappings having known proximity corrections; and
correcting a geometry of the memory cell to be printed according to a known proximity correction that matches the mapped set of neighbors.

9. The method of claim 8, wherein correcting a geometry comprises:
adjusting the size and shape of the cell to be printed to compensate for proximity effects.

10. A method, comprising:
analyzing a set of nearest neighbors to a cell;
generating a proximity pattern based on the analysis of the nearest neighbors;
matching the generated proximity pattern with a table of known proximity patterns; and
correcting the cell printing geometry based on a correction for the matched proximity pattern.

11. The method of claim 10, wherein the cell printing geometry includes corrections for shape.

12. The method of claim 10, wherein the cell printing geometry includes correction for size.

13. A method of printing cells in a ROM embedded DRAM, comprising:
determining a maximum distance at which proximity effects will be considered;
determining a configuration of cells around a cell to be printed;
comparing the determined configuration against a table of known configurations; and
printing the cell with a correction associated with the known configuration that matches the determined configuration.

14. The method of claim 13, wherein comparing comprises:
looking up in the table the determined configuration of cells around the cell to be printed; and
retrieving a proximity correction associated with the known configuration that matches the determined configuration.

15. A method of printing contacts in a ROM embedded DRAM, comprising:
analyzing a pattern of predefined neighbors to a contact to be printed;
selecting a printing pattern for the contact from a lookup table containing possible nearest neighbor combinations; and
printing the contact with the selected printing pattern.

16. The method of claim 15, wherein analyzing a pattern of predefined neighbors comprises analyzing the nearest neighbors to the contact.

17. The method of claim 15, wherein analyzing a pattern of predefined neighbors comprises analyzing the first and the second nearest neighbors to the contact.

18. A method, comprising:
analyzing a set of nearest neighbors to a memory placement to be printed on a memory array; and
correcting a geometry of the memory placement before printing based on the analysis of the set of nearest neighbors.

19. The method of claim 18, wherein correcting a geometry comprises:
comparing the set of nearest neighbors to a known set of nearest neighbors each having a proximity correction;
retrieving the proximity correction for one of the known set of nearest neighbors that matches the set of nearest neighbors; and
applying the retrieved proximity correction to the memory placement.

20. The method of claim 18, wherein correcting the geometry includes correcting for shape.

21. The method of claim 18, wherein correcting the geometry includes correcting for size.

22. The method of claim 18, wherein correcting the geometry includes mirroring.

23. The method of claim 18, wherein correcting the geometry includes translating.

24. The method of claim 18, wherein correcting the geometry includes rotating.

25. A ROM embedded DRAM, comprising:
a random access memory having a first portion programmable as a read only memory and a second portion programmable as a random access memory, the second portion having a proximity corrected printing layout.

26. The ROM embedded DRAM of claim 25, wherein the proximity corrected printing layout comprises a plurality of printed cells, each cell being a proximity corrected printed cell.

27. The ROM embedded DRAM of claim 25, wherein the proximity corrected printed cell is printed with proximity corrections generated through analysis of a configuration of cells surrounding the cell.

28. The ROM embedded DRAM of claim 27, wherein the cells surrounding the cell comprise the nearest neighbors to the cell.

29. The ROM embedded DRAM of claim 27, wherein the cells surrounding the cell comprise the nearest neighbors and the second nearest neighbors to the cell.

30. The ROM embedded DRAM of claim 27, wherein the cells surrounding the cell comprise the neighbors that affect the cell proximity.

31. A processing system, comprising:
a processor; and
a read only memory embedded dynamic random access memory device coupled to the processor and comprising:
a random access memory having a first portion programmable as a read only memory and a second portion programmable as a random access memory, the second portion having a proximity corrected printing layout.

32. The processing system of claim 31, wherein the proximity corrected printing layout comprises a plurality of printed cells, each cell being a proximity corrected printed cell.

33. The processing system of claim 31, wherein the proximity corrected printed cell is printed with proximity corrections generated through analysis of a configuration of cells surrounding the proximity corrected cell.

34. The processing system of claim 33, wherein the cells surrounding the proximity corrected cell comprise the nearest neighbors to the proximity corrected cell.

35. The processing system of claim 33, wherein the cells surrounding the proximity corrected cell comprise the nearest neighbors and the second nearest neighbors to the proximity corrected cell.

36. The processing system of claim 33, wherein the cells surrounding the proximity corrected cell comprise the neighbors that affect the cell proximity.

37. A method for making proximity corrections in integrated circuit printing, comprising:
analyzing a predetermined set of neighbors to a position to be printed; and
determining a printing pattern for the position based on the analysis of the predetermined set of neighbors.

38. The method of claim 37, wherein determining a printing pattern comprises:
looking up proximity effects for the set of neighbors in a lookup table of known proximity effects for the integrated circuit.

39. The method of claim 38, wherein looking up a proximity correction comprises:
identifying a pattern of nearest neighbors; and
matching the pattern to one of a plurality of stored patterns in a lookup table.

40. A method for printing patterns in a programmable array, comprising:
identifying nearest neighbors to a position to be printed in the array;
looking up a proximity correction for the position; and
printing a proximity corrected pattern in the position.

41. The method of claim 40, wherein looking up a proximity correction comprises looking up a correction matching the identified set of nearest neighbors from a lookup table containing a plurality of corrections corresponding to potential corrections for the programmable array.

42. The method of claim 40, wherein printing a proximity corrected pattern comprises:
applying a proximity correction to the position to be printed; and
printing the position with the proximity correction.

43. The method of claim 40, and further comprising:
determining if one or more positions to be printed have a symmetry; and
printing mirrored placements for mirror symmetry positions.

44. A method of making proximity corrections at a programming level of a programmable array, comprising:
identifying a position to be printed;
determining a set of nearest neighbors to the position to be printed;
correcting a printing pattern for the position based on the determined set of nearest neighbors; and
printing the corrected pattern at the position.

45. A method for making proximity corrections in a large array with non-standard feature placement, comprising:
analyzing a predetermined set of neighbors to a feature to be printed; and
determining a printing pattern for the feature based on the analysis of the predetermined set of neighbors.

46. The method of claim 45, wherein determining a printing pattern comprises:
looking up proximity effects for the set of neighbors in a lookup table of known proximity effects for the large array.

47. The method of claim 45, wherein looking up a proximity correction comprises:
identifying a pattern of nearest neighbors; and
matching the pattern to one of a plurality of stored patterns in a lookup table.
